(19) United States
(12) Patent Application Publication
(10) Pub. No.: US 2011/0014732 A1
(43) Pub. Date: Jan. 20, 2011

(54) LIGHT-EMITTING MODULE FABRICATION METHOD

(76) Inventor: Je-Hsiang LEE, Taipei (TW)

Correspondence Address: Muncy, Geissler, Olds & Lowe, PLLC, 4000 Legato Road, Suite 310, FAIRFAX, VA, 22033, US

(21) Appl. No.: 12/505,967

(22) Filed: Jul. 20, 2009

(51) Int. Cl. H01L 33/00

(52) U.S. Cl. 438/27; 438/28; 257/E33.061; 257/E33.057; 257/E33.066

(57) ABSTRACT

A light-emitting module fabrication method includes the steps of (a) forming component contacts and positive-bonding and negative-bonding contacts on a circuit layout on a substrate, (b) electrically bonding the pins of electronic components to the component contacts and P-electrode bonding pads and N-electrode bonding pads of light-emitting chips to the positive-bonding and negative-bonding contacts at the substrate, (c) employing a coating technique to cover light-emitting surfaces of each of the light-emitting chips with a respective phosphor layer, and (d) employing a curing technique to cure the phosphor layers.

### BACKGROUND OF THE INVENTION

1. Field of the Invention

The present invention relates to the fabrication of light-emitting modules and more particularly, to a simple light-emitting module fabrication method, which has a phosphor and resin mixture be directly covered on light-emitting chips after bonding of electronic components and light-emitting chips to circuit contacts on a substrate, and then the phosphor layers formed of the phosphor and resin mixture are cured, finishing the production of the desired light-emitting module.

2. Description of the Related Art

Many different types of light emitting devices are known. Following the development of the next green generation, LEDs (light emitting diodes), more particularly, white LEDs are intensively used in street lights, tunnel lights, hand lights, signboards, home illumination and backlights for display panel for the advantages of small size and low power consumption.

Conventionally, the fabrication of a light-emitting module for LED lamp is to employ a white light processing step to light emitting diode chips on a substrate. White light of a light emitting diode is formed by means of mixing light rays of the three prime colors (RGB). Multiple different colors of light-emitting chips can be arranged together to produce white light. Alternatively, a phosphor powder can be mixed with a transparent or semitransparent adhesive subject to a predetermined ratio and then coated on blue or ultraviolet light-emitting diode dies on a substrate by means of a gluing technique, for example, spot-gluing technique. After baking to cure the phosphor powder and adhesive mixture, a cutting procedure is employed to cut the substrate, so that semi-finished products of light emitting diode chips are obtained. The semi-finished products are then examined through a quality examination process. Each semi-finished product is then placed in a reflective cup, and then covered with a transparent adhesive by means of a mold casting technique, forming a light emitting diode. A number of light emitting diodes can then be bonded to contacts on a circuit board by means of SMT (surface mount technology), forming a LED module. This LED module fabrication method is complicated, requiring much manufacturing time. In consequence, the manufacturing cost according to this fabrication method is high.

Further, yield rate is quite important in mass production of a product. Due to complicated manufacturing procedures, the defective rate of the fabrication of LED modules according to the aforesaid prior art fabrication method is high. Further, because a quality examination process is performed after formation of semi-finished products, i.e., after the baking process to cure the phosphor powder and adhesive mixture and the cutting procedure to cut the substrate for obtaining semi-finished products of light emitting diode chips, a big mount of phosphor powder and adhesive mixture is wasted when semi-finished products are rejected during quality examination. In consequence, the material cost according to the aforesaid prior art LED module fabrication method is high.

Therefore, it is desirable to provide a light-emitting module fabrication method, which eliminates the aforesaid problems.

### SUMMARY OF THE INVENTION

The present invention has been accomplished under the circumstances in view. It is the main object of the present invention to provide a light-emitting module fabrication method, which simplifies the fabrication of light-emitting modules, improves the yield rate of the fabrication of light-emitting modules, shortens the manufacturing time of light-emitting modules and reduces the manufacturing cost of light-emitting modules.

To achieve these and other objects of the present invention, a light-emitting module fabrication method is for making a light-emitting module by means of: forming circuit contacts on a substrate and electrically bonding electronic components and light-emitting chips to the circuit contacts, and then employing a coating technique to cover light-emitting surfaces of each light-emitting chip with a respective phosphor layer, and then employing a curing technique to cure the phosphor layers.

Further, the light-emitting chips are bonded to the circuit contacts at the substrate by means of a flip chip mounting technique so that each light-emitting chip provides five blue or ultraviolet light-emitting surfaces. The phosphor layers are respectively covered over the five blue or ultraviolet light-emitting surfaces of each of the light-emitting chips for producing white light, avoiding leakage of blue or ultraviolet light.

Further, a screen printing or mold casting technique is employed to cover the phosphor layers on the light-emitting chips by means of. During coating of the phosphor layers, multiple light-emitting chips can be accommodated in one open space of the stainless steel screen or in one cavity of a steel mold subject to the coating technique employed, so that one phosphor layer covers multiple light-emitting chips to form a cubic configuration for emitting light evenly.

### BRIEF DESCRIPTION OF THE DRAWINGS

FIG. 1 is a sectional side view of a light-emitting module in accordance with the present invention.

FIG. 2 is a light-emitting module fabrication flow according to the present invention.

FIG. 3 is a schematic drawing showing the application of a screen printing technique for the formation of phosphor layers on the light-emitting chips according to the present invention.

FIG. 4 is a schematic drawing showing the application of a mold casting technique for the formation of phosphor layers on the light-emitting chips according to the present invention.

FIG. 5 is a sectional view of a light-emitting lamp constructed according to the present invention.

FIG. 6 is an oblique elevation of the light-emitting lamp shown in FIG. 5.

### DETAILED DESCRIPTION OF THE PREFERRED EMBODIMENT

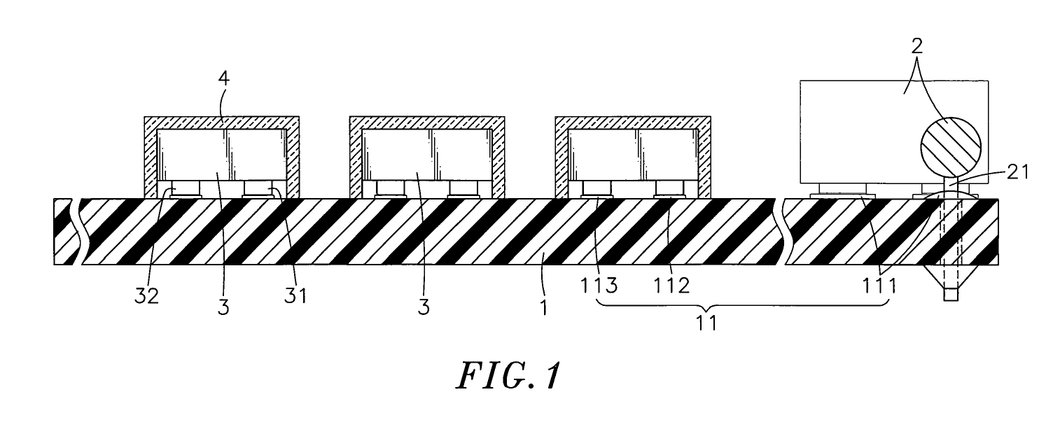

Referring to FIG. 1, a light-emitting module in accordance with the present invention is shown comprising a substrate 1, electronic components 2 installed in the substrate 1, a plurality of light-emitting chips 3 formed on the substrate 1, and phosphor layers 4 covering each of the light-emitting elements 3.

The substrate 1 has circuits 10 arranged thereon, and a plurality of circuit contacts 11 formed on the circuits 10. The circuit contacts 11 include multiple component contacts 111, multiple positive-bonding contacts 112 and multiple negative-bonding contacts 113. The positive-bonding contacts 112 and multiple negative-bonding contacts 113 are arranged in pairs. Further, the substrate 1 can have the circuits 10 arranged on its one side. Alternatively, the substrate 1 can have the circuits 10 arranged on its two opposite sides.

The electronic components 2 can be capacitors, resistors and/or control chips, each having a plurality of pins 21 electrically connected to respective component contacts 111 at the substrate 1.

The light-emitting chips 3 are rectangular chips having six surfaces. Further, the light-emitting chips 3 are of flip chip design, each having a P-electrode bonding pad 31 and an N-electrode bonding pad 32 on one surface thereof. By means of flip chip packaging technology, the P-bonding pads 31 and N-bonding pads 32 of the light-emitting chips 3 are respectively electrically bonded to the positive-bonding contacts 112 and negative-bonding contacts 113 of the substrate 1.

The phosphor layers 4 cover each of the light-emitting chips 3. The phosphor layers 4 are formed of a mixture of a phosphor and a transparent or semitransparent adhesive subject to a predetermined ratio. The adhesive can be epoxy resin or silicon rubber.

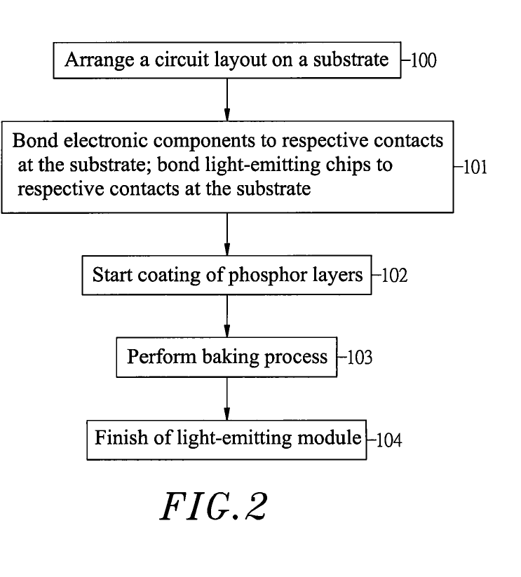

Referring to FIGS. 2˜4 and FIG. 1 again, the fabrication of the aforesaid light-emitting module includes the steps:
(100) Prepare a substrate 1 and create circuits 10 on the substrate 1, and then form circuit contacts 11 on the circuits 10, wherein the circuit contacts 11 include component contacts 111 and positive-bonding contacts 112 and negative-bonding contacts 113.
(101) Bond pins 21 of selected electronic components 2 to the component contacts 111 on the substrate 1 respectively electrically, and then respectively electrically bond P-electrode bonding pads 31 and N-electrode bonding pads 32 of light-emitting chips 3 to the positive-bonding contacts 112 and negative-bonding contacts 113 at the circuits 10 of the substrate 1.
(102) Employ a coating technique to cover the light-emitting surfaces of each of the light-emitting chips 3 with a respective phosphor layer 4.
(103) Employ a curing technique to the phosphor layer 4 coated light-emitting chips 3 to have the phosphor layers 4 be cured and shape formed on the light-emitting surfaces of the light-emitting chips 3.
(104) Finish the desired light-emitting module.

During fabrication, circuits 10 are created on a substrate 1, and then circuit contacts 11 are formed on the circuits 10, and then the pins 21 of prepared electronic components 2 are respectively electrically bonded to component contacts 111 of the circuit contacts 11, and then P-electrode bonding pads 31 and N-electrode bonding pads 32 of prepared light-emitting chips 3 are respectively electrically bonded to the positive-bonding contacts 112 and negative-bonding contacts 113 of the circuit contacts 11. By means of the circuits 10, the light-emitting chips 3 are electrically connected in parallel or in series. After the light-emitting chips 3 have been electrically connected to the circuit contacts 11 at the substrate 1, each light-emitting chip 3 provides five light-emitting surfaces. Further, the circuits 10 can be created on one single side of the substrate 1 to form a single-sided circuit board, or on the two opposite sides of the substrate 1 to form a double-sided circuit board. The electronic components 2 and the light-emitting chips 3 can be bonded to the circuit contacts 11 at one side the substrate 1 to form a single-sided light-emitting module. Alternatively, the electronic components 2 and the light-emitting chips 3 can be bonded to the circuit contacts 11 at the two opposite sides the substrate 1 to form a double-sided light-emitting module. Further, before bonding to the circuit contacts 11 at the substrate 1, the light-emitting chips 3 must be examined through a quality examination procedure. Only perfect quality products that passed the examination are used. Further, conducting adhesive and solder material such as silver paste, solder ball, solder bumps or solder paste may be used to facilitate bonding of the electronic components 2 and the light-emitting chips 3 to the circuit contacts 11 at the substrate 1. Further, the electronic components 2 can be bonded to the circuit contacts 11 at the substrate 1 by means of SMT (surface mount technique) or through-hole mounting techniques. Further, the light-emitting chips 3 are bonded to the circuit contacts 11 at the substrate 1 by means of SMT (surface mount technique). After bonding of the electronic components 2 and the light-emitting chips 3 to the circuit contacts 11 at the substrate 1, a coating technique is employed to cover the phosphor layers 4 on the light-emitting chips 3.

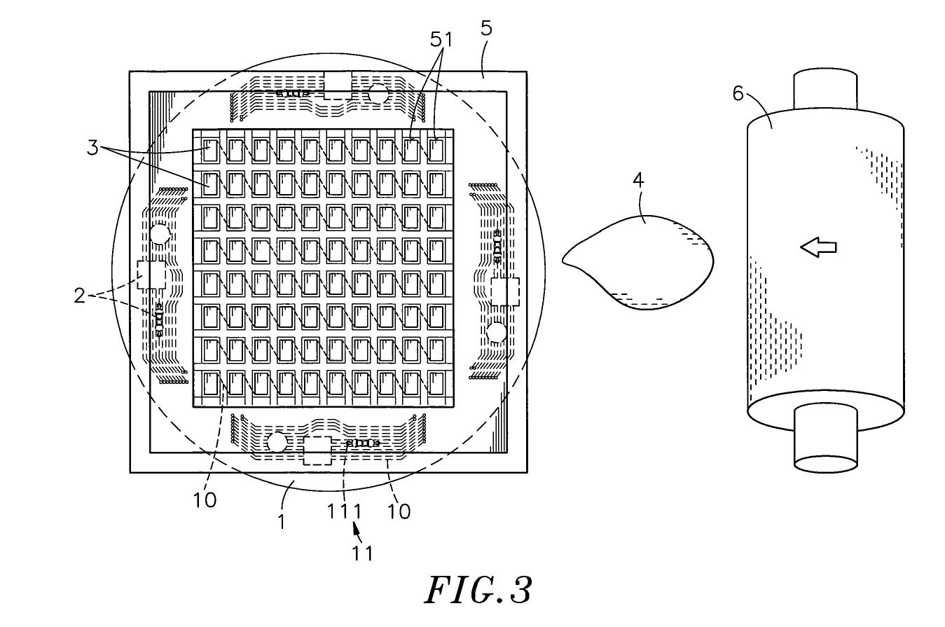

The coating technique to cover the phosphor layers 4 on the light-emitting chips 3 can be screen printing or mold casting. When screen printing is adopted, as shown in FIG. 3, a stainless steel screen 5 having a predetermined thickness is placed atop the substrate 1. The stainless steel screen 5 has open spaces 51 corresponding to the light-emitting chips 3 at the substrate 1. The prepared phosphor and adhesive mixture for phosphor layer is placed on a plane in flush with the top surface of the stainless steel screen 5. The operator operates a fill roller 6 to move the phosphor and adhesive mixture for phosphor layer over the top surface of the stainless steel screen 5, forcing the phosphor and adhesive mixture to pass through the open spaces 51 in the stainless steel screen 5 so that phosphor layers 4 are formed of the phosphor and adhesive mixture on the top surface of the substrate 1 and covered over the light-emitting chips 3 respectively. By means of using the fill roller 6 to force the phosphor and adhesive mixture through the open spaces 51 in the stainless steel screen 5, bubbles will not be produced in the phosphor layers 4. After the light-emitting chips 3 have been covered by the phosphor layers 4, a curing process is employed. After curing, the stainless steel screen 5 is removed from the substrate 1, and the phosphor layers 3 are hardened and shape-formed on the light-emitting chips 3.

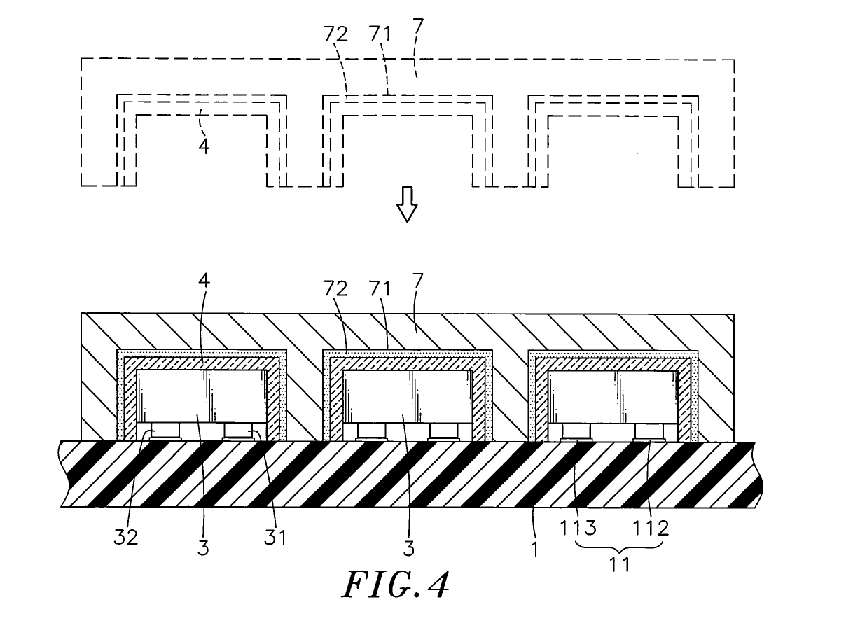

Further, when mold casting is employed to cover the phosphor layers 4 on the light-emitting chips 3, as shown in FIG. 4, a steel mold 7 having cavities 71 is used, and then a mold-release agent 72 is coated on the surface of each of the cavities 71, and then a predetermined amount of the prepared phosphor and adhesive mixture is filled in the cavities 71 of the steel mold 7, and then the steel mold 7 is attached to the substrate 1 to have the cavities 71 with the phosphor and adhesive mixture be covered on the light-emitting chips 3, and then the substrate 1 with the steel mold 7 are baked to cure the phosphor and adhesive mixture so that the desired phosphor layers 4 are formed of phosphor and adhesive mixture on the light-emitting chips 3, and then the steel mold 7 is removed from the substrate 1. Thus, the phosphor layers 4 are shape-formed on the light-emitting chips 3.

The aforesaid baking procedure is to heat the substrate 1 with the attached steel mold 7 in a baking oven to have the phosphor and adhesive mixture be evenly distributed and covered on the substrate 1 over the light-emitting surfaces of each of the light-emitting chips 3 and cured, thereby forming the desired phosphor layers 4 on the light-emitting chips 3.

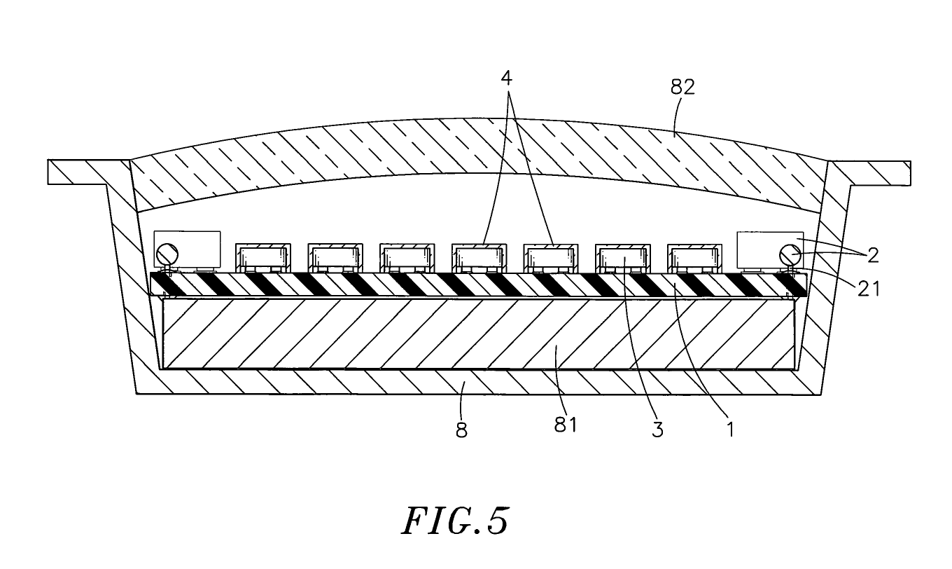

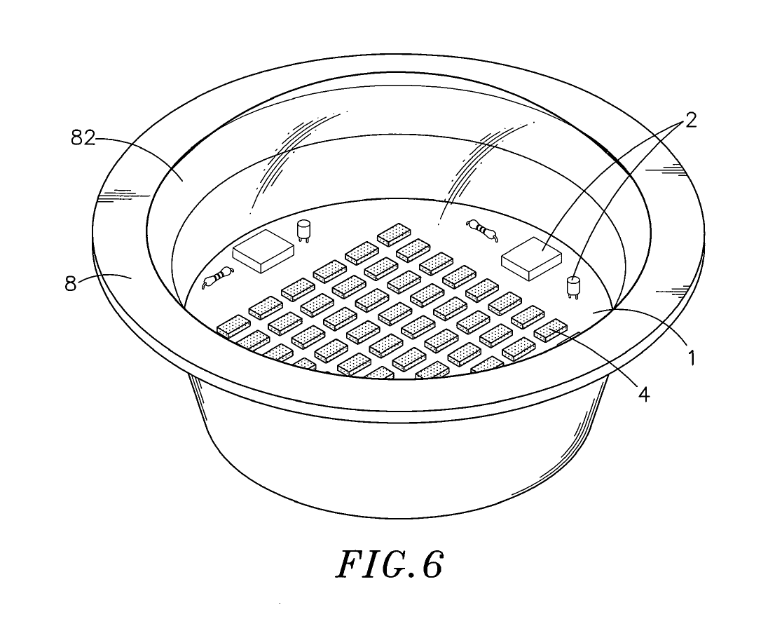

FIGS. 5 and 6 show an application example of the present invention. As illustrates, the light-emitting module is mounted in a lamp housing 8 and kept in close contact with a bottom heat-transfer block 81 in the lamp housing 8. The lamp housing 8 has the front open side thereof covered with a lens 82 through which emitted light go from the light-emitting chips 3 of the light-emitting module to the outside.

According to the aforesaid preferred embodiment of the present invention, the light-emitting chips 3 have a rectangular configuration. When two adjacent light-emitting chips 3 are received in one open space 51 in the stainless steel screen 5 or in one cavity 71 of the steel mold 7 during procedure to form the phosphor layers 4, the phosphor and adhesive mixture is covered on each two adjacent light-emitting chips 3, thereby forming a cubic phosphor layer 4 on each two adjacent light-emitting chips 3, i.e., multiple light-emitting chips 3 are covered by one phosphor layer 4 to constitute a light-emitting chip set.

As stated above, the invention provides a light-emitting module fabrication method, which has the following features and advantages:

1. The invention has circuit contacts 11 created on a circuit layout on a substrate 1 for the bonding of electronic components 2 and light-emitting chips 3 electrically, and employs a screen printing or mold casting technique to have the light-emitting surfaces of the installed light-emitting chips 3 be covered with phosphor layers 4 so that a light-emitting module is obtained after curing of the phosphor layers 4. This light-emitting module fabrication method is quite simple, saving much the manufacturing time.

2. Before bonding to the circuit contacts 11 at the substrate 1, the prepared light-emitting chips 3 must be examined through a quality examination procedure. Only perfect quality light-emitting chips 3 that passed the examination are used, avoiding production of a defective product.

3. The light-emitting chips 3 can be sapphire-based epitaxial layers or ultraviolet epitaxial layers. Further, the light-emitting chips 3 are rectangular chips having six planes. When a single-sided flip chip bonding technique is employed to bond the light-emitting chips 3 to the circuit contacts 11 at the substrate 1, each light-emitting chip 3 provides five light-emitting surfaces. After formation of the phosphor layers 4 on the light-emitting chips 3, each light-emitting chip 3 emits white light through the 5 light-emitting surfaces thereof evenly, avoiding side leakage of blue light rays or ultraviolet light rays.

4. Each open space 51 in the stainless steel screen 5 or each cavity 71 of the steel mold 5 can be defined to accommodate multiple light-emitting chips 3 so that one phosphor layer 4 can be formed on multiple light-emitting chips 3 to constitute a cubit light-emitting chip set that emits light evenly in different directions.

5. The invention has the light-emitting chips 3 be directly electrically bonded to the circuit contacts 11 at the substrate 1, and the prepared phosphor and resin mixture be directly covered on the light-emitting chips 3 to form the desired phosphor layers 4 after through a curing process. Unlike the conventional techniques of molding a transparent adhesive after coating of a phosphor powder and curing of the phosphor coating, the invention simplifies the fabrication of the light-emitting module.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A light-emitting module fabrication method, comprising the steps of:
(a) preparing a substrate and creating circuits on said substrate, and then forming component contacts and positive-bonding and negative-bonding contacts on said circuits;
(b) electrically bonding pins of selected electronic components to said component contacts, and then respectively electrically bonding P-electrode bonding pads and N-electrode bonding pads of selected light-emitting chips to said positive-bonding and negative-bonding contacts at said circuits of said substrate;
(c) employing a coating technique to cover light-emitting surfaces of each of said light-emitting chips with a respective phosphor layer; and
(d) employing a curing technique to cure said phosphor layers.

2. The light-emitting module fabrication method as claimed in claim 1, wherein the pins of said electronic components are bonded to said component contacts by one of SMT (surface mount technology) and through-hole mounting technology.

3. The light-emitting module fabrication method as claimed in claim 1, wherein the P-electrode bonding pads and N-electrode bonding pads of said light-emitting chips are bonded to said positive-bonding and negative-bonding contacts by SMT (surface mount technology).

4. The light-emitting module fabrication method as claimed in claim 1, wherein the P-electrode bonding pads and N-electrode bonding pads of said light-emitting chips are bonded to said positive-bonding and negative-bonding contacts by means of a silver paste.

5. The light-emitting module fabrication method as claimed in claim 1, wherein the P-electrode bonding pads and N-electrode bonding pads of said light-emitting chips are bonded to said positive-bonding and negative-bonding contacts by means of solder balls.

6. The light-emitting module fabrication method as claimed in claim 1, wherein the P-electrode bonding pads and N-electrode bonding pads of said light-emitting chips are bonded to said positive-bonding and negative-bonding contacts by means of solder paste.

7. The light-emitting module fabrication method as claimed in claim 1, wherein the coating technique to cover said phosphor layers on said light-emitting chips is a screen printing technique comprising the sub-steps of (i) preparing a stainless steel screen having a predetermined thickness and a number of open spaces and then placing said stainless steel screen atop said substrate; (ii) preparing a phosphor and adhesive mixture and placing said phosphor and adhesive mixture on a plane in flush with the topmost edge of said stainless steel screen; (iii) operating a fill roller to move said phosphor and adhesive mixture over said stainless steel screen and to force said phosphor and adhesive mixture through the open spaces in said stainless steel screen so that phosphor layers are formed of said phosphor and adhesive mixture on said substrate and covered over said light-emitting chips.

8. The light-emitting module fabrication method as claimed in claim 7, wherein each open space of said stainless steel screen accommodate at least two of said light-emitting chips when said stainless steel screen is placed atop said substrate.

9. The light-emitting module fabrication method as claimed in claim 1, wherein the coating technique to cover said phosphor layers on said light-emitting chips is a mold casting technique comprising the sub-steps of (i) preparing a steel mold having a plurality of cavities in a predetermined pattern; (ii) coating a mold-release agent on the surface of each of said cavities; (iii) preparing a phosphor and adhesive mixture and then filling a predetermined amount of the prepared phosphor and adhesive mixture in said cavities of said steel mold; and (iv) attaching said steel mold to said substrate to have said cavities and said phosphor and adhesive mixture be covered on said light-emitting chips and molded into phosphor layers on said light-emitting chips for receiving the processing process of said curing technique where said substrate and said steel mold with said phosphor layers are backed in a baking oven to have said phosphor layers be cured, and then said steel mold is removed from said substrate after curing of said phosphor layers.

10. The light-emitting module fabrication method as claimed in claim 9, wherein each cavity of said steel mold accommodate at least two of said light-emitting chips when said steel mold is attached to said substrate.

11. The light-emitting module fabrication method as claimed in claim 1, wherein said light-emitting chips are rectangular chips bonded to said positive-bonding and negative-bonding contacts by a flip chip bonding technique so that said light-emitting chips each provide 5 light-emitting surfaces after bonding of the P-electrode bonding pads and N-electrode bonding pads thereof to the respective positive-bonding and negative-bonding contacts at said circuits of said substrate.

12. The light-emitting module fabrication method as claimed in claim 10, wherein said phosphor layers cover the 5 light-emitting surfaces of each of said light-emitting chips.

13. The light-emitting module fabrication method as claimed in claim 1, wherein said curing technique is to bake said phosphor layers with said substrate in a baking oven, curing said phosphor layers.
